(19) United States
(12) Patent Application Publication
(10) Pub. No.: US 2025/0218525 A1
(43) Pub. Date: Jul. 3, 2025

(54) SEMICONDUCTOR CHIP THAT ADJUSTS STROBE SIGNAL DELAY

(71) Applicant: SK hynix Inc., Icheon-si Gyeonggi-do (KR)

(72) Inventors: Kyung Jun CHO, Icheon-si Gyeonggi-do (KR); Jae Hyung PARK, Icheon-si Gyeonggi-do (KR)

(73) Assignee: SK hynix Inc., Icheon-si Gyeonggi-do (KR)

(21) Appl. No.: 18/675,660

(22) Filed: May 28, 2024

(30) Foreign Application Priority Data
Dec. 28, 2023 (KR) 10-2023-0194981

(51) Int. Cl. G11C 29/12; G11C 29/14

(52) U.S. Cl. CPC G11C 29/12015; G11C 29/1201; G11C 29/14

(57) ABSTRACT

A memory chip includes a delay amount adjustment circuit configured to change a logic level combination of a code signal that adjusts a first delay amount for a strobe signal that is input or output through a conductive via based on a chip ID and a test mode signal after the start of a post-training operation and configured to generate an op-code signal by performing an arithmetic operation on the code signal and a data processing circuit configured to delay the strobe signal by a second delay amount that is based on the op-code signal, configured to latch internal data in synchronization with the strobe signal that is delayed by the second delay amount, and configured to output, as data, the internal data that are latched.

### CROSS-REFERENCE TO RELATED APPLICATION

The present application claims priority under 35 U.S.C. § 119 (a) to Korean Patent Application No. 10-2023-0194981, filed in the Korean Intellectual Property Office on Dec. 28, 2023, the entire contents of which application is incorporated herein by reference.

### BACKGROUND

The present disclosure relates to a semiconductor chip that adjusts the delay amount for a strobe signal that is input to and output from outside the semiconductor chip.

In general, access to a memory chip may be performed through a controller. For example, after the start of data read for the memory chip, a host transmits a read command and an address to the controller. The controller reads data from the memory chip and transmits the read data to the host. After the start of data write for the memory chip, the host transmits a write command, write data, and an address to the controller. The controller writes the write data into a memory device. In such an access process for the memory chip, strobe signals that strobe data that are input to and output from memory chips may be generated at different times due to process, voltage, and temperature (PVT) variation.

### SUMMARY

In an embodiment, a memory chip may include a delay amount adjustment circuit configured to change a logic level combination of a code signal that adjusts a first delay amount for a strobe signal that is input or output through a conductive via based on a chip identification and a test mode signal after the start of a post-training operation and configured to generate an op-code signal by performing an arithmetic operation on the code signal and a data processing circuit configured to delay the strobe signal by a second delay amount that is based on the op-code signal, configured to latch internal data in synchronization with the strobe signal that is delayed by the second delay amount, and configured to output, as data, the internal data that are latched.

In an embodiment, a semiconductor chip may include a first memory chip configured to generate a first op-code signal by performing an arithmetic operation on a first code signal that adjusts a delay amount for a strobe signal that is input through a first conductive via when a chip identification (ID) is at a first logic level combination after a start of a post-training operation and configured to output first data to a second conductive via by delaying the strobe signal by a delay amount that is adjusted based on the first op-code signal and a second memory chip configured to generate a second op-code signal by performing an arithmetic operation on a second code signal that adjusts the delay amount for the strobe signal that is input through the first conductive via when the chip identification is at a second logic level combination after the start of the post-training operation, and configured to output second data through a third conductive via by delaying the strobe signal by a delay amount that is adjusted based on the second op-code signal.

In an embodiment, a semiconductor chip may include a first memory chip, associated with a first chip identification (ID), configured to, in response to receiving the first chip ID, generate a first op-code signal by performing an arithmetic operation on a first code signal that adjusts a delay amount for a strobe signal that is input through a first signal path and adjust the delay amount for the strobe signal based on the first op-code signal and a second memory chip, associated with a second chip identification (ID), configured to, in response to receiving the second chip ID, generate a second op-code signal by performing an arithmetic operation on a second code signal that adjusts the delay amount for the strobe signal that is input through a second signal path and adjust the delay amount for the strobe signal based on the second op-code signal.

In an embodiment, a method may include generating an op-code signal by performing an arithmetic operation on a code signal that adjusts a delay amount for a strobe signal; adjusting the delay amount for the strobe signal based on the op-code signal; delaying the strobe signal by the adjusted delay amount; latching internal data in synchronization with the strobe signal that is delayed by the adjusted delay amount; and outputting the latched internal data.

### BRIEF DESCRIPTION OF THE DRAWINGS

FIG. 1 is a block diagram illustrating a semiconductor chip according to an embodiment of the present disclosure.

FIG. 2 is a block diagram illustrating an embodiment of a first memory chip.

FIG. 3 is a table including logic level combinations of a chip ID that select memory chips.

FIG. 4 is a block diagram illustrating an embodiment of a training circuit.

FIG. 5 and FIG. 6 are tables including values related to an operation of an operation control signal generation circuit.

FIG. 7 is a block diagram illustrating an embodiment of an offset code signal generation circuit.

FIG. 8 and FIG. 9 are tables including values related to an operation of an offset code signal generation circuit.

FIG. 10 is a block diagram illustrating an embodiment of an offset selection circuit.

FIG. 11 is a block diagram illustrating an embodiment of an arithmetic circuit.

FIG. 12 is a block diagram illustrating an embodiment of a code selection circuit.

FIG. 13 is a block diagram illustrating another embodiment of a code selection circuit.

FIG. 14 through FIG. 16 are tables including values related to a post-training operation of the semiconductor chip according to an embodiment of the present disclosure.

FIG. 17 is a diagram illustrating an embodiment of an electronic system including a semiconductor chip.

### DETAILED DESCRIPTION

In the descriptions of the following embodiments, the term “preset” indicates that the numerical value of a parameter is previously decided, for example, prior to or when the parameter is used in a process or algorithm. According to an embodiment, the numerical value of the parameter may be determined when the process or algorithm is started or while the process or algorithm is performed.

Terms such as “first” and “second,” which are used to distinguish among various components, do not limit the components. For example, a first component may be referred to as a second component, and vice versa, in different embodiments. A decimal value is a base 10 value, and a binary value is a base 2 value as used throughout the detailed description.

When a component is referred to as “coupled” or “connected” to another component, the components may be directly coupled or connected to each other or coupled or connected to each other through another component interposed between the components. In contrast, when a component is referred to as being “directly coupled” or “directly connected” to another component, the components are directly coupled or connected to each other without another component interposed between the components.

A “logic high level” and a “logic low level” are used to describe the logic levels of signals. A signal at a “logic high level” is distinguished from a signal at a “logic low level.” For example, when a signal at a first voltage corresponds to a signal at a “logic high level,” a signal at a second voltage corresponds to a signal at a “logic low level.” According to an embodiment, a “logic high level” is associated with a voltage higher than a voltage associated with a “logic low level.” According to an embodiment, the logic levels of signals may be at different logic levels or opposite logic levels. For example, a signal at a logic high level may be at a logic low level in some embodiments, and a signal at a logic low level may be at a logic high level in some embodiments.

Various embodiments of the present disclosure are described in more detail with reference to the accompanying drawings. The embodiments are only used to exemplify the present disclosure, and the scope of the present disclosure is not limited by the embodiments.

A training operation that adjusts the timing at which the strobe signals are generated is performed. Such a training operation may be used in a semiconductor chip in which a plurality of memory chips is stacked. The semiconductor chip may be implemented by stacking a plurality of memory chips using a plurality of electrically conductive through silicon vias (TSV) (hereinafter referred to as “conductive vias”). The stacking memory chips may include high bandwidth memory (HBM) or may be implemented by stacking a plurality of memory chips through wire bonding.

Embodiments of the present disclosure provide a semiconductor chip that adjusts the delay amount for a strobe signal that is input to and output from outside the semiconductor chip.

According to embodiments of the present disclosure, adjusting the delay amount for a strobe signal is possible by changing a logic level combination of a code signal that adjusts the delay amount for the strobe signal in a memory chip that is selected by a chip ID after the start of a post-training operation.

According to embodiments of the present disclosure, variously adjusting the delay amount for a strobe signal is possible by performing various arithmetic operations on a logic level combination of a code signal that adjusts the delay amount for the strobe signal in a memory chip that is selected by a chip ID after the start of a post-training operation.

According to embodiments of the present disclosure, flexibly adjusting the delay amount for a strobe signal is possible by generating a code signal that adjusts the delay amount for the strobe signal in a pre-training operation and additionally changing a logic level combination of the code signal after the start of a post-training operation.

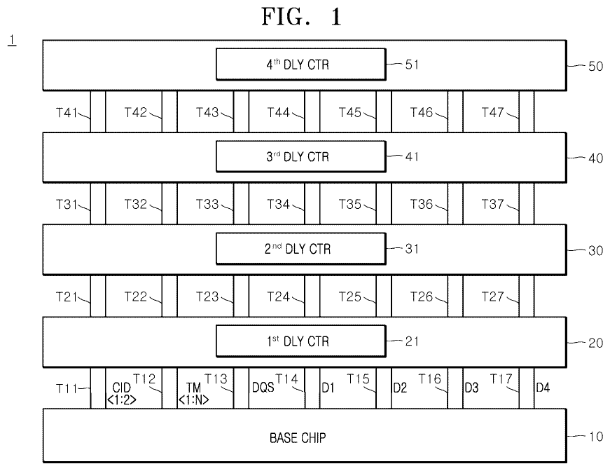

As illustrated in FIG. 1, a semiconductor chip 1 according to an embodiment of the present disclosure includes a base chip 10, a first memory chip 20, a second memory chip 30, a third memory chip 40, and a fourth memory chip 50.

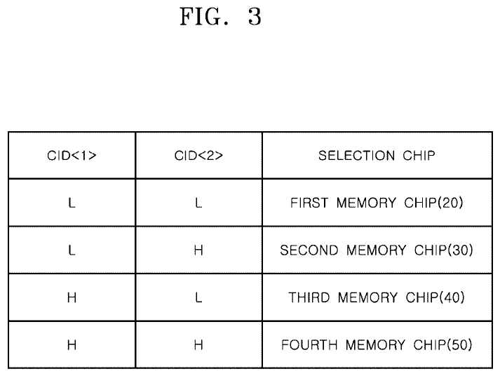

The base chip 10 is connected to conductive vias T11 through T17. The base chip 10 outputs a chip identification (chip ID) CID<1:2> through the conductive via T11. The base chip 10 outputs a test mode signal TM<1:N> through the conductive via T12. The base chip 10 outputs a strobe signal DQS through the conductive via T13 and receives the strobe signal DQS through the conductive via T13. The base chip 10 outputs first data D1 through the conductive via T14 and receives the first data D1 through the conductive via T14. The base chip 10 outputs second data D2 through the conductive via T15 and receives the second data D2 through the conductive via T15. The base chip 10 outputs third data D3 through the conductive via T16 and receives the third data D3 through the conductive via T16. The base chip 10 outputs fourth data D4 through the conductive via T17 and receives the fourth data D4 through the conductive via T17. The chip ID CID<1:2> is output in the form of a logic level combination for use in selecting the first memory chip 20, the second memory chip 30, the third memory chip 40, and the fourth memory chip 50. The chip ID CID<1:2> may be sequentially counted and output according to an embodiment. The logic level combination of the chip ID CID<1:2> that selects the first memory chip 20, the second memory chip 30, the third memory chip 40, and the fourth memory chip 50 is described in detail with reference to FIG. 3. The chip ID CID<1:2> is implemented using 2 bits in this example, but may be implemented using various different quantities of bits in order to select a plurality of memory chips according to an embodiment, for example, 3 bits to address up to 8 memory chips, 4 bits to address up to 16 memory chips, and so forth. The test mode signal TM<1:N> is a signal including information related to performing an arithmetic operation that adjusts the delay amount for the strobe signal DQS after the start of a post-training operation. The test mode signal TM<1:N> is implemented to include N bits, but may be implemented to include various different quantities of bits according to an embodiment. The first data D1 may include a plurality of bits, may be data that are output in order to be stored in the first memory chip 20 after the start of a write operation, and may be data that are output from the first memory chip 20 after the start of a read operation. The second data D2 may include a plurality of bits, may be data that are output in order to be stored in the second memory chip 30 after the start of a write operation, and may be data that are output from the second memory chip 30 after the start of a read operation. The third data D3 may include a plurality of bits, may be data that are output in order to be stored in the third memory chip 40 after the start of a write operation, and may be data that are output from the third memory chip 40 after the start of a read operation. The fourth data D4 may include a plurality of bits, may be set as data that are output in order to be stored in the fourth memory chip 50 after the start of a write operation, and may be set as data that are output from the fourth memory chip 50 after the start of a read operation. The conductive vias T11 through T17 are first signal paths on which signals are transmitted between the base chip 10 and the first memory chip 20.

The first memory chip 20 is connected to the conductive vias T11 through T17 and the conductive vias T21 through T27. The first memory chip 20 is stacked over the base chip 10 and the conductive vias T11 through T17. The first memory chip 20 receives the chip ID CID<1:2> through the conductive via T11. The first memory chip 20 receives the test mode signal TM<1:N> through the conductive via T12. The first memory chip 20 receives the strobe signal DQS through the conductive via T13 and outputs the strobe signal DQS through the conductive via T13. The first memory chip 20 receives the first data D1 through the conductive via T14 and outputs the first data D1 through the conductive via T14. The first memory chip 20 receives the second data D2 through the conductive via T15 and outputs the second data D2 through the conductive via T15. The first memory chip 20 receives the third data D3 through the conductive via T16 and outputs the third data D3 through the conductive via T16. The first memory chip 20 receives the fourth data D4 through the conductive via T17 and outputs the fourth data D4 through the conductive via T17. The conductive vias T21 through T27 are second signal paths on which signals are transmitted between the first memory chip 20 and the second memory chip 30.

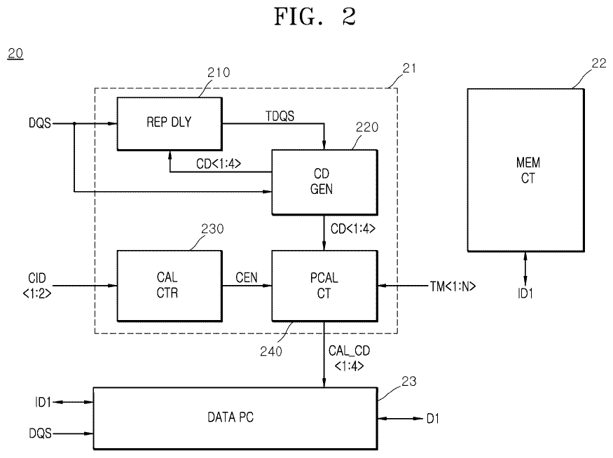

The first memory chip 20 includes a first delay amount adjustment circuit 1^{st} DLY CTR 21. The first delay amount adjustment circuit 21 generates a code signal CD<1:4> in FIG. 2 that adjusts a first delay amount for the strobe signal DQS through a replica delay circuit REP DLY 210 in FIG. 2 including, storing, duplicating, or having the delay amount for the conductive via T13 after the start of a pre-training operation. The first delay amount adjustment circuit 21 changes a logic level combination of the code signal CD<1:4> in FIG. 2 that adjusts the first delay amount for the strobe signal DQS based on the chip ID CID<1:2> and the test mode signal TM<1:N> after the start of a post-training operation. The first delay amount adjustment circuit 21 generates an op-code signal CAL_CD<1:4> in FIG. 2 by performing an arithmetic operation on the code signal CD<1:4> in FIG. 2 after the start of a post-training operation. The pre-training operation is an operation including generating the code signal CD<1:4> in FIG. 2 that adjusts the delay amount for the strobe signal DQS that is input to or output from outside the semiconductor chip 1 before the semiconductor chip 1 begins operations. The post-training operation is an operation including changing a logic level combination of the code signal CD<1:4> in FIG. 2 that is generated in a pre-training operation after the semiconductor chip 1 begins operations.

The conductive via T11 may be electrically connected to the conductive via T21. The conductive via T12 may be electrically connected to the conductive via T22. The conductive via T13 may be electrically connected to the conductive via T23. The conductive via T14 may be electrically connected to the conductive via T24. The conductive via T15 may be electrically connected to the conductive via T25. The conductive via T16 may be electrically connected to the conductive via T26. The conductive via T17 may be electrically connected to the conductive via T27.

The second memory chip 30 is connected to the conductive vias T21 through T27 and the conductive vias T31 through T37. The second memory chip 30 is stacked over the first memory chip 20 and the conductive vias T21 through T27. The second memory chip 30 receives the chip ID CID<1:2> through the conductive via T21. The second memory chip 30 receives the test mode signal TM<1:N> through the conductive via T22. The second memory chip 30 receives the strobe signal DQS through the conductive via T23 and outputs the strobe signal DQS through the conductive via T23. The second memory chip 30 receives the first data D1 through the conductive via T24 and outputs the first data D1 through the conductive via T24. The second memory chip 30 receives the second data D2 through the conductive via T25 and outputs the second data D2 through the conductive via T25. The second memory chip 30 receives the third data D3 through the conductive via T26 and outputs the third data D3 through the conductive via T26. The second memory chip 30 receives the fourth data D4 through the conductive via T27 and outputs the fourth data D4 through the conductive via T27. The conductive vias T31 through T37 are third signal paths on which signals are transmitted between the second memory chip 30 and the third memory chip 40.

The second memory chip 30 includes a second delay amount adjustment circuit 2^{nd} DLY CTR 31. The second delay amount adjustment circuit 31 generates a code signal that adjusts the first delay amount for the strobe signal DQS through a replica delay circuit including, storing, duplicating, or having the delay amount for the conductive vias T13 and T23 after the start of a pre-training operation. The second delay amount adjustment circuit 31 changes a logic level combination of the code signal that adjusts the first delay amount for the strobe signal DQS based on the chip ID CID<1:2> and the test mode signal TM<1:N> after the start of a post-training operation. The second delay amount adjustment circuit 31 generates an op-code signal by performing an arithmetic operation on the code signal after the start of a post-training operation.

The conductive via T21 may be electrically connected to the conductive via T31. The conductive via T22 may be electrically connected to the conductive via T32. The conductive via T23 may be electrically connected to the conductive via T33. The conductive via T24 may be electrically connected to the conductive via T34. The conductive via T25 may be electrically connected to the conductive via T35. The conductive via T26 may be electrically connected to the conductive via T36. The conductive via T27 may be electrically connected to the conductive via T37.

The third memory chip 40 is connected to the conductive vias T31 through T37 and the conductive vias T41 through T47. The third memory chip 40 is stacked over the second memory chip 30 and the conductive vias T31 through T37. The third memory chip 40 receives the chip ID CID<1:2> through the conductive via T31. The third memory chip 40 receives the test mode signal TM<1:N> through the conductive via T32. The third memory chip 40 receives the strobe signal DQS through the conductive via T33 and outputs the strobe signal DQS through the conductive via T33. The third memory chip 40 receives the first data D1 through the conductive via T34 and outputs the first data D1 through the conductive via T34. The third memory chip 40 receives the second data D2 through the conductive via T35 and outputs the second data D2 through the conductive via T35. The third memory chip 40 receives the third data D3 through the conductive via T36 and outputs the third data D3 through the conductive via T36. The third memory chip 40 receives the fourth data D4 through the conductive via T37 and outputs the fourth data D4 through the conductive via T37. The conductive vias T41 through T47 are fourth signal paths on which signals are transmitted between the third memory chip 40 and the fourth memory chip 50.

The third memory chip 40 includes a third delay amount adjustment circuit 3^{rd} DLY CTR 41. The third delay amount adjustment circuit 41 generates a code signal that adjusts the first delay amount for the strobe signal DQS through a replica delay circuit including, storing, duplicating, or having the delay amount for the conductive vias T13, T23, and T33 after the start of a pre-training operation. The third delay amount adjustment circuit 41 changes a logic level combination of the code signal that adjusts the first delay amount for the strobe signal DQS based on the chip ID CID<1:2> and the test mode signal TM<1:N> after the start of a post-training operation. The third delay amount adjustment circuit 41 generates an op-code signal by performing an arithmetic operation on the code signal (after the start of a post-training operation.

The conductive via T31 may be electrically connected to the conductive via T41. The conductive via T32 may be electrically connected to the conductive via T42. The conductive via T33 may be electrically connected to the conductive via T43. The conductive via T34 may be electrically connected to the conductive via T44. The conductive via T35 may be electrically connected to the conductive via T45. The conductive via T36 may be electrically connected to the conductive via T46. The conductive via T37 may be electrically connected to the conductive via T47.

The fourth memory chip 50 is connected to the conductive vias T41 through T47. The fourth memory chip 50 is stacked over the third memory chip 40 and the conductive vias T41 through T47. The fourth memory chip 50 receives the chip ID CID<1:2> through the conductive via T41. The fourth memory chip 50 receives the test mode signal TM<1:N> through the conductive via T42. The fourth memory chip 50 receives the strobe signal DQS through the conductive via T43 and outputs the strobe signal DQS through the conductive via T43. The fourth memory chip 50 receives the first data D1 through the conductive via T44 and outputs the first data D1 through the conductive via T44. The fourth memory chip 50 receives the second data D2 through the conductive via T45 and outputs the second data D2 through the conductive via T45. The fourth memory chip 50 receives the third data D3 through the conductive via T46 and outputs the third data D3 through the conductive via T46. The fourth memory chip 50 receives the fourth data D4 through the conductive via T47 and outputs the fourth data D4 through the conductive via T47.

The fourth memory chip 50 includes a fourth delay amount adjustment circuit 4^{th} DLY CTR 51. The fourth delay amount adjustment circuit 51 generates a code signal that adjusts the first delay amount for the strobe signal DQS through a replica delay circuit including, storing, duplicating, or having the delay amount for the conductive via T13, T23, T33, and T43 after the start of a pre-training operation. The fourth delay amount adjustment circuit 51 changes a logic level combination of the code signal that adjusts the first delay amount for the strobe signal DQS based on the chip ID CID<1:2> and the test mode signal TM<1:N> after the start of a post-training operation. The fourth delay amount adjustment circuit 51 generates an op-code signal by performing an arithmetic operation on the code signal after the start of a post-training operation.

In FIG. 1, the first through fourth memory chips 20, 30, 40, and 50 are implemented as stacked over the base chip 10, although various quantities of memory chips, such as 8 and 16, may be implemented as stacked over the base chip 10 according to various embodiments.

The semiconductor chip 1 illustrated in FIG. 1 is implemented by stacking the base chip 10 and the first through fourth memory chips 20, 30, 40, and 50 through the through (TSV) electrodes like high bandwidth memory (HBM), but may be implemented such that a plurality of memory chips is stacked with wire bonding according to an embodiment. The pieces or segments of wire bonding comprise signal paths over which signals are input to and output from the base chip 10 and the first through fourth memory chips 20, 30, 40, and 50 according to an embodiment.

FIG. 2 is a block diagram illustrating an embodiment of the first memory chip 20, for example, as included in the semiconductor chip 1. The first memory chip 20 includes a first delay amount adjustment circuit 21, a memory circuit MEM CT 22, and a data processing circuit DATA PC 23.

The first delay amount adjustment circuit 21 includes the replica delay circuit REP DLY 210, a code signal generation circuit CD GEN 220, a training control circuit CAL CTR 230, and a training circuit PCAL CT 240.

The replica delay circuit 210 receives the strobe signal DQS through the conductive via T13. The replica delay circuit 210 generates a transfer strobe signal TDQS by delaying the strobe signal DQS by a first delay amount. The replica delay circuit 210 generates the transfer strobe signal TDQS by delaying the strobe signal DQS by the first delay amount that is adjusted based on the code signal CD<1:4>. The first delay amount for the replica delay circuit 210 may be adjusted equally with the delay amount for the conductive via T13 based on the code signal CD<1:4>. The code signal CD<1:4> is implemented to include 4 bits, but may be implemented to include other quantities of bits according to various embodiments.

The code signal generation circuit 220 generates the code signal CD<1:4> by comparing the phases of the strobe signal DQS and the transfer strobe signal TDQS after the start of a pre-training operation. The code signal generation circuit 220 adjusts a logic level combination of the code signal CD<1:4> by comparing the phases of the strobe signal DQS and the transfer strobe signal TDQS after the start of a pre-training operation. The code signal generation circuit 220 changes a logic level combination of the code signal CD<1:4> when the phases of the strobe signal DQS and the transfer strobe signal TDQS are different from each other after the start of a pre-training operation. The code signal generation circuit 220 adjusts a logic level combination of the code signal CD<1:4> when the phase of the strobe signal DQS is the same as the phase of the transfer strobe signal TDQS after the start of a pre-training operation.

The training control circuit 230 receives the chip ID CID<1:2> through the conductive via T11. The training control circuit 230 generates an operation enable signal CEN based on the chip ID CID<1:2> after the start of a post-training operation. The training control circuit 230 generates the operation enable signal CEN that is enabled when the chip ID CID<1:2> is at a set, preset, or predetermined logic level combination after the start of a post-training operation. The training control circuit 230 generates the operation enable signal CEN that is enabled when a first bit CID<1> of the chip ID is at a logic low level and a second bit CID<2> of the chip ID is at a logic low level after the start of a post-training operation.

The training circuit 240 receives the test mode signal TM<1:N> through the conductive via T12. The training circuit 240 changes a logic level combination of the code signal CD<1:4> based on the test mode signal TM<1:N> when the operation enable signal CEN is enabled after the start of a post-training operation. The training circuit 240 generates the op-code signal CAL_CD<1:4> by performing an arithmetic operation on the code signal CD<1:4> after the start of a post-training operation. The op-code signal CAL_CD<1:4> is implemented to include 4 bits, but may be implemented to include other quantities of bits according to various embodiments.

The first delay amount adjustment circuit 21 generates the code signal CD<1:4> that adjusts the first delay amount for the strobe signal DQS through the replica delay circuit 210 including, storing, duplicating, or having the delay amount for the conductive via T13 after the start of a pre-training operation. The first delay amount adjustment circuit 21 changes a logic level combination of the code signal CD<1:4> that adjusts the first delay amount for the strobe signal DQS based on the chip ID CID<1:2> and the test mode signal TM<1:N> after the start of a post-training operation. The first delay amount adjustment circuit 21 generates the op-code signal CAL_CD<1:4> by performing an arithmetic operation on the code signal CD<1:4> after the start of a post-training operation.

The memory circuit 22 outputs first internal data ID1 that are stored in the memory circuit 22 after the start of a read operation. The memory circuit 22 is implemented to output the first internal data ID1 that are stored in the memory circuit 22 after the start of a read operation, but may be implemented to store the first internal data ID1 that are generated from the first data D1 after the start of a write operation. The memory circuit 22 may be implemented as a common memory cell array circuit including a plurality of memory cells (not illustrated).

The data processing circuit 23 receives the strobe signal DQS through the conductive via T13. The data processing circuit 23 delays the strobe signal DQS by a second delay amount that is based on the op-code signal CAL_CD<1:4>. The data processing circuit 23 latches the first internal data ID1 in synchronization with the strobe signal DQS that is delayed by the second delay amount. The data processing circuit 23 outputs, as the first data D1, the first internal data ID1 that are latched. The data processing circuit 23 outputs the first data D1 to the base chip 10 through the conductive via T14. The data processing circuit 23 is implemented to generate the first data D1 from the first internal data ID1 after the start of a read operation, but may be implemented to generate the first internal data ID1 from the first data D1 after the start of a write operation.

FIG. 3 is a table including logic level combinations of the chip ID CID<1:2> that select, for example, the first through fourth memory chips 20, 30, 40, and 50 illustrated in FIG. 1.

When the first bit CID<1> of the chip ID is at a logic low level L and the second bit CID<2> of the chip ID is at a logic low level L, the first memory chip 20 is selected and a post-training operation is performed. An example in which the first bit CID<1> of the chip ID is at a logic low level L and the second bit CID<2> of the chip ID is at a logic low level L is a first logic level combination.

When the first bit CID<1> of the chip ID is at a logic low level L and the second bit CID<2> of the chip ID is at a logic high level H, the second memory chip 30 is selected and a post-training operation is performed. An example in which the first bit CID<1> of the chip ID is at a logic low level L and the second bit CID<2> of the chip ID is at a logic high level H is a second logic level combination.

When the first bit CID<1> of the chip ID is at a logic high level H and the second bit CID<2> of the chip ID is at a logic low level L, the third memory chip 40 is selected, and a post-training operation is performed. An example in which the first bit CID<1> of the chip ID is at a logic high level H and the second bit CID<2> of the chip ID is at a logic low level L is a third logic level combination.

When the first bit CID<1> of the chip ID is at a logic high level H and the second bit CID<2> of the chip ID is at a logic high level H, the fourth memory chip 50 is selected and a post-training operation is performed. An example in which the first bit CID<1> of the chip ID is at a logic high level H and the second bit CID<2> of the chip ID is at a logic high level H is a fourth logic level combination.

Once the first and second bits of the chip ID CID<1:2> are sequentially counted and input to the memory chips 20, 30, 40, and 50, all post-training operations are completed.

The second through fourth memory chips 30, 40, and 50 may each be implemented using the same construction or circuitry as the first memory chip 20 illustrated in FIG. 2 and may perform the same operations as performed by the first memory chip 20 as described above.

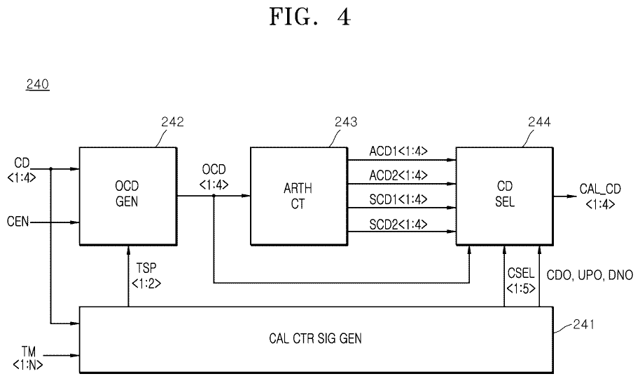

FIG. 4 is a block diagram illustrating an embodiment of the training circuit 240, for example, as included in the first delay amount adjustment circuit 21 of FIG. 2. The training circuit 240 includes an operation control signal generation circuit CAL CTR SIG GEN 241, an offset code signal generation circuit OCD GEN 242, an arithmetic circuit ARTH CT 243, and a code selection circuit CD SEL 244.

The operation control signal generation circuit 241 generates a test offset signal TSP<1:2> that changes the logic level combination of the code signal CD<1:4> based on the test mode signal TM<1:N>. The operation control signal generation circuit 241 generates an operation selection signal CSEL<1:5> that selects the results of an arithmetic operation based on the test mode signal TM<1:N>. The operation control signal generation circuit 241 detects an input value of the code signal CD<1:4>, and generates a code output signal CDO, an upper limit output signal UPO, and a lower limit output signal DNO that select an upper limit value and a lower limit value based on the test mode signal TM<1:N>. The test offset signal TSP<1:2> is implemented to include 2 bits, but may be implemented to include other quantities of bits according to various embodiments. The operation selection signal CSEL<1:5> is implemented to include 5 buts, but may be implemented to include other quantities of bits according to various embodiments.

The offset code signal generation circuit 242 generates an offset code signal OCD<1:4> based on the code signal CD<1:4> and the operation enable signal CEN. The offset code signal generation circuit 242 detects input values of the code signal CD<1:4> and generates the offset code signal OCD<1:4> by changing a logic level combination of the code signal CD<1:4> based on the operation enable signal CEN and the test offset signal TSP<1:2>. The offset code signal generation circuit 242 detects input values of the code signal CD<1:4> and generates the offset code signal OCD<1:4> by changing the input values of the code signal CD<1:4> based on the operation enable signal CEN and the test offset signal TSP<1:2>.

The arithmetic circuit 243 generates a first addition code signal ACD1<1:4>, a second addition code signal ACD2<1:4>, a first subtraction code signal SCD1<1:4>, and a second subtraction code signal SCD2<1:4> by performing an arithmetic operation on the offset code signal OCD<1:4>. The arithmetic circuit 243 generates the first addition code signal ACD1<1:4> by performing a first addition operation on the offset code signal OCD<1:4>. The arithmetic circuit 243 generates the second addition code signal ACD2<1:4> by performing a second addition operation on the offset code signal OCD<1:4>. The arithmetic circuit 243 generates the first subtraction code signal SCD1<1:4> by performing a first subtraction operation on the offset code signal OCD<1:4>. The arithmetic circuit 243 generates the second subtraction code signal SCD2<1:4> by performing a second subtraction operation on the offset code signal OCD<1:4>. Each of the first addition code signal ACD1<1:4>, the second addition code signal ACD2<1:4>, the first subtraction code signal SCD1<1:4>, and the second subtraction code signal SCD2<1:4> is implemented to include 4 bits, but may be implemented to include other quantities of bits according to various embodiments.

The code selection circuit 244 outputs any one of the offset code signal OCD<1:4>, the first addition code signal ACD1<1:4>, the second addition code signal ACD2<1:4>, the first subtraction code signal SCD1<1:4>, and the second subtraction code signal SCD2<1:4> as the op-code signal CAL_CD<1:4> based on the operation selection signal CSEL<1:5>, the code output signal CDO, the upper limit output signal UPO, and the lower limit output signal DNO.

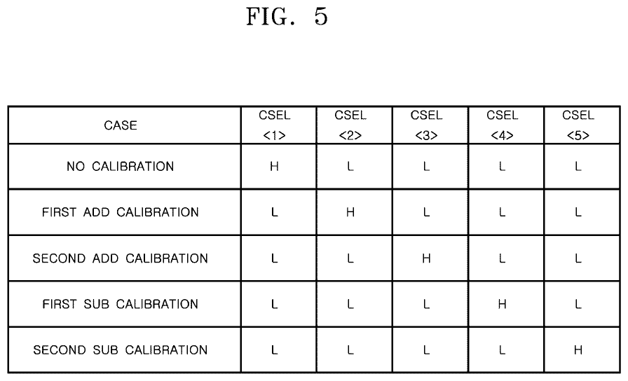

FIG. 5 is a table including values related to an operation including generating the operation selection signal CSEL<1:5> that selects the results of an arithmetic operation, for example, in the operation control signal generation circuit 241 illustrated in FIG. 4.

In the example in which results without an arithmetic operation are selected, NO CALIBRATION, the operation control signal generation circuit 241 generates a first bit CSEL<1> of the operation selection signal enabled at a logic high level based on the test mode signal TM<1:N> and generates bits CSEL<2>, CSEL<3>, CSEL<4>, and CSEL<5> at a logic low level.

In the example in which the results of a first addition operation are selected, FIRST ADD CALIBRATION, the operation control signal generation circuit 241 generates a second bit CSEL<2> of the operation selection signal enabled at a logic high level based on the test mode signal TM<1:N> and generates bits CSEL<1>, CSEL<3>, CSEL<4>, and CSEL<5> at a logic low level.

In the example in which the results of a second addition operation are selected, SECOND ADD CALIBRATION, the operation control signal generation circuit 241 generates a third bit CSEL<3> of the operation selection signal enabled at a logic high level based on the test mode signal TM<1:N> and generates bits CSEL<1>, CSEL<2>, CSEL<4>, and CSEL<5> at a logic low level.

In the example in which the results of a first subtraction operation are selected, FIRST SUB CALIBRATION, the operation control signal generation circuit 241 generates a fourth bit CSEL<4> of the operation selection signal enabled at a logic high level based on the test mode signal TM<1:N> and generates bits CSEL<1>, CSEL<2>, CSEL<3>, and CSEL<5> at a logic low level.

In the example in which the results of a second subtraction operation are selected, SECOND SUB CALIBRATION, the operation control signal generation circuit 241 generates a fifth bit CSEL<5> of the operation selection signal enabled at a logic high level based on the test mode signal TM<1:N> and generates bits CSEL<1>, CSEL<2>, CSEL<3>, and CSEL<4> at a logic low level.

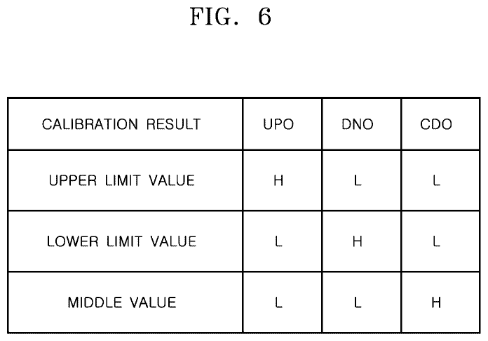

FIG. 6 is a table including values related to an operation including generating the code output signal CDO, the upper limit output signal UPO, and the lower limit output signal DNO that selects an upper limit value and a lower limit value based on the results of an arithmetic operation, for example, in the operation control signal generation circuit 241 illustrated in FIG. 4.

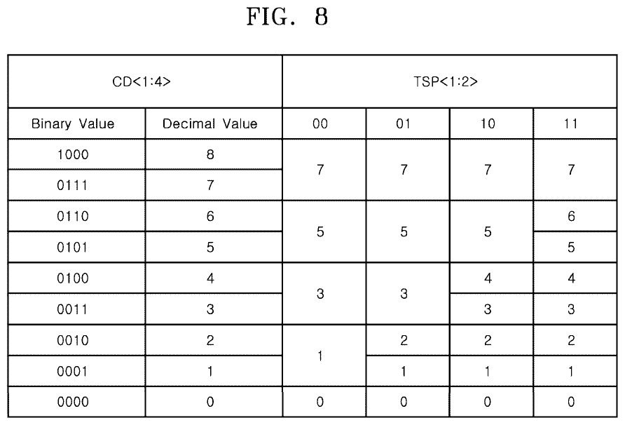

In the example in which the upper limit value is selected as the result of an arithmetic operation, UPPER LIMIT VALUE, the operation control signal generation circuit 241 detects an input value of the code signal CD<1:4> and generates the upper limit output signal UPO that is enabled at a logic high level H in order to select the upper limit value based on the test mode signal TM<1:N>, while the lower limit output signal DNO and the code output signal CDO are each generated at a logic low level L. An example in which the upper limit value is selected as the result of the arithmetic operation UPPER LIMIT VALUE includes when a logic level combination of the op-code signal OCD<1:4> is up-counted beyond or above a decimal value “8” in FIG. 8 by the arithmetic operation on the code signal CD<1:4>. For example, when the logic level combination of the op-code signal OCD<1:4> is up-counted beyond the decimal value “8” may indicate that the op-code signal OCD<1:4> is generated as “1001” when an input value of the code signal CD<1:4> is input as a binary value “0111” and a second addition operation (two instances of up-counting) is performed. When the logic level combination of the op-code signal OCD<1:4> is up-counted beyond the decimal value “8” may indicate that the op-code signal OCD<1:4> is generated as “1001” when an input value of the code signal CD<1:4> is input as a binary value “1000” and a first addition operation (one instance of up-counting) is performed.

In the example in which the lower limit value is selected as the results of an arithmetic operation, LOWER LIMIT VALUE, the operation control signal generation circuit 241 detects an input value of the code signal CD<1:4> and generates the lower limit output signal DNO enabled at a logic high level H in order to select the lower limit value based on the test mode signal TM<1:N>, while the upper limit output signal UPO and the code output signal CDO are each generated at a logic low level L. An example in which the lower limit value is selected as the result of the arithmetic operation, LOWER LIMIT VALUE, includes when a logic level combination of the op-code signal OCD<1:4> is down-counted beyond or below a decimal value “0” in FIG. 8 by the arithmetic operation on the code signal CD<1:4>. For example, when the logic level combination of the op-code signal OCD<1:4> is down-counted beyond the decimal value “0” may indicate that an input value of the code signal CD<1:4> is a binary value “0001” and a second subtraction operation (two instances of down-counting) is performed, resulting in the op-code signal OCD<1:4> generated as “1111”. When the logic level combination of the op-code signal OCD<1:4> is down-counted beyond the decimal value “0” may indicate that an input value of the code signal CD<1:4> is a binary value “0000” and a first subtraction operation (one instance of down-counting) is performed, the op-code signal OCD<1:4> is generated as “1111”.

In the example in which a middle value is selected as the results of an arithmetic operation, MIDDLE VALUE, the operation control signal generation circuit 241 detects an input value of the code signal CD<1:4> and generates the code output signal CDO enabled at a logic high level H in order to select the middle value based on the test mode signal TM<1:N>, while the upper limit output signal UPO and the lower limit output signal DNO are each generated at a logic low level L. An example in which the middle value is selected as the result of the arithmetic operation MIDDLE VALUE includes when a logic level combination of the op-code signal OCD<1:4> is up-counted from “0” or down-counted from “8” in FIG. 8 by the result of the arithmetic operation on the code signal CD<1:4>. For example, when the logic level combination of the op-code signal OCD<1:4> is up-counted from “0” may indicate that an input value of the code signal CD<1:4> is a binary value “0000” and a first addition operation (one instance of up-counting) is performed, resulting in the op-code signal OCD<1:4> generated as “0001”. For example, when the logic level combination of the op-code signal OCD<1:4> is down-counted from “8” may indicate that an input value of the code signal CD<1:4> is a binary value “1000” and a first subtraction operation (one instance of down-counting) is performed, resulting in the op-code signal OCD<1:4> generated as “0111”.

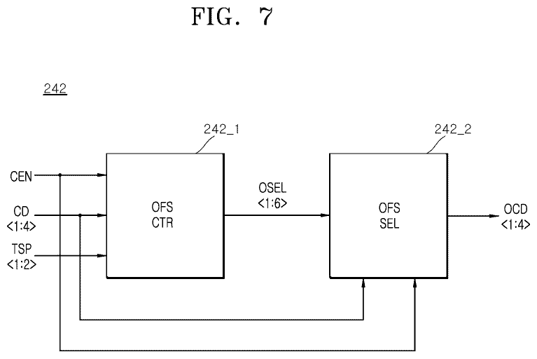

FIG. 7 is a block diagram illustrating an embodiment of the offset code signal generation circuit 242, for example, as included in the training circuit 240. The offset code signal generation circuit 242 includes an offset control circuit OFS CTR 242_1 and an offset selection circuit OFS SEL 242_2.

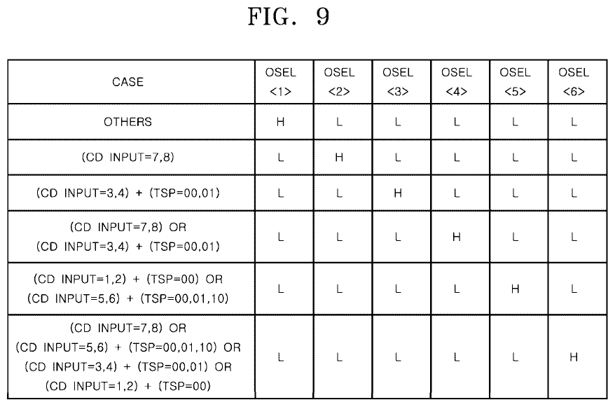

The offset control circuit 242_1 detect an input value of the code signal CD<1:4>. The offset control circuit 242_1 generates an offset selection signal OSEL<1:6> based on input values of the code signal CD<1:4>, the operation enable signal CEN, and the test offset signal TSP<1:2>. An operation including generating, by the offset control circuit 242_1, the offset selection signal OSEL<1:6> is described in detail with reference to FIG. 8 and FIG. 9. The offset selection signal OSEL<1:6> is implemented to include 6 bits, but may be implemented to include other quantities of bits according to various embodiments.

The offset selection circuit 242_2 generates the offset code signal OCD<1:4> by changing a logic level combination of the code signal CD<1:4> based on the operation enable signal CEN and the offset selection signal OSEL<1:6>. An operation including generating, by the offset selection circuit 242_2, the offset code signal OCD<1:4> is described in detail with reference to FIG. 8 and FIG. 9.

FIG. 8 and FIG. 9 are tables including values related to an operation of the offset code signal generation circuit 242, for example, as illustrated in FIG. 7.

An operation including detecting, by the offset control circuit 242_1, an input value of the code signal CD<1:4> is described as follows with reference to FIG. 8.

The offset control circuit 242_1 detects an input value of the code signal CD<1:4>. The offset code signal generation circuit 242 detects that the input value is “0” when a binary value of the code signal CD<1:4> is “0000”. The example in which the input value is “0” indicates a decimal value is “0”. The offset control circuit 242_1 detects that the input value is “1” when a binary value of the code signal CD<1:4> is “0001”. The example in which the input value is “1” indicates a decimal value is “1”. The offset control circuit 242_1 detects that the input value is “2” when a binary value of the code signal CD<1:4> is “0010”. The example in which the input value is “2” indicates a decimal value is “2”. The offset control circuit 242_1 detects that the input value is “3” when a binary value of the code signal CD<1:4> is “0011”. The example in which the input value is “3” indicates a decimal value is “3”. The offset control circuit 242_1 detects that the input value is “4” when a binary value of the code signal CD<1:4> is “0100”. The example in which the input value is “4” indicates a decimal value is “4”. The offset control circuit 242_1 detects that the input value is “5” when a binary value of the code signal CD<1:4> is “0101”. The example in which the input value is “5” indicates a decimal value is “5”. The offset control circuit 242_1 detects that the input value is “6” when a binary value of the code signal CD<1:4> is “0110”. The example in which the input value is “6” indicates a decimal value is “6”. The offset control circuit 242_1 detects that the input value is “7” when a binary value of the code signal CD<1:4> is “0111”. The example in which the input value is “7” indicates a decimal value is “7”. The offset control circuit 242_1 detects that the input value is “8” when a binary value of the code signal CD<1:4> is “1000”. The example in which the input value is “8” indicates a decimal value is “8”.

An operation including generating, by the offset control circuit 242_1, the offset selection signal OSEL<1:6> based on an input value of the code signal CD<1:4> and the test offset signal TSP<1:2> is described as follows with reference to FIG. 9.

The offset control circuit 242_1 generates a sixth bit OSEL<6> of the offset selection signal at a logic high level H when input values of the code signal CD<1:4> are decimal values “7” or “8”. The offset control circuit 242_1 generates the sixth bit OSEL<6> of the offset selection signal at a logic high level H when input values of the code signal CD<1:4> are decimal values “5” or “6” and logic level combinations of the test offset signal TSP<1:2> are “00”, “01”, or “10”. The offset control circuit 242_1 generates the sixth bit OSEL<6> of the offset selection signal at a logic high level H when input values of the code signal CD<1:4> are decimal values “3” or “4” and logic level combinations of the test offset signal TSP<1:2> are “00” or “01”. The offset control circuit 242_1 generates the sixth bit OSEL<6> of the offset selection signal at a logic high level H when input values of the code signal CD<1:4> are decimal values “1” or “2” and a logic level combination of the test offset signal TSP<1:2> is “00”. When the sixth bit OSEL<6> of the offset selection signal is generated at a logic high level H, the first bit OSEL<1>, the second bit OSEL<2>, the third bit OSEL<3>, the fourth bit OSEL<4>, and the fifth bit OSEL<5> are generated at a logic low level L.

The offset control circuit 242_1 generates a fifth bit OSEL<5> of the offset selection signal at a logic high level H when input values of the code signal CD<1:4> are decimal values “1” or “2” and a logic level combination of the test offset signal TSP<1:2> is “00”. The offset control circuit 242_1 generates the fifth bit OSEL<5> of the offset selection signal at a logic high level H when input values of the code signal CD<1:4> are decimal values “5” or “6” and logic level combinations of the test offset signal TSP<1:2> are “00”, “01”, or “10”. When the fifth bit OSEL<5> of the offset selection signal is generated at a logic high level H, the first bit OSEL<1>, the second bit OSEL<2>, the third bit OSEL<3>, the fourth bit OSEL<4>, and the sixth bit OSEL<6> are generated at a logic low level L.

The offset control circuit 242_1 generates a fourth bit OSEL<4> of the offset selection signal at a logic high level H when input values of the code signal CD<1:4> are decimal values “7” or “8”. The offset control circuit 242_1 generates the fourth bit OSEL<4> of the offset selection signal at a logic high level H when input values of the code signal CD<1:4> are decimal values “3” or “4” and logic level combinations of the test offset signal TSP<1:2> are “00” or “01”. When the fourth bit OSEL<4> of the offset selection signal is generated at a logic high level H, the first bit OSEL<1>, the second bit OSEL<2>, the third bit OSEL<3>, the fifth bit OSEL<5>, and the six bit OSEL<6> are generated at a logic low level L.

The offset control circuit 242_1 generates a third bit OSEL<3> of the offset selection signal at a logic high level H when input values of the code signal CD<1:4> are decimal values “3” or “4” and logic level combinations of the test offset signal TSP<1:2> are “00” or “01”. When the third bit OSEL<3> of the offset selection signal is generated at a logic high level H, the first bit OSEL<1>, the second bit OSEL<2>, the fourth bit OSEL<4>, the fifth bit OSEL<5>, and the six bit OSEL<6> are generated at a logic low level L.

The offset control circuit 242_1 generates a second bit OSEL<2> of the offset selection signal at a logic high level H when input values of the code signal CD<1:4> are decimal values “7” or “8”. When the second bit OSEL<2> of the offset selection signal is generated at a logic high level H, the first bit OSEL<1>, the third bit OSEL<3>, the fourth bit OSEL<4>, the fifth bit OSEL<5>, and the six bit OSEL<6> are generated at a logic low level L.

The offset control circuit 242_1 generates a first bit OSEL<1> of the offset selection signal at a logic high level H for the remaining input values OTHERS other than input values of the code signal CD<1:4> and logic level combinations of the test offset signal TSP<1:2> that generate the second through sixth bits OSEL<2:6> of the offset selection signal at a logic high level H. When the first bit OSEL<1> of the offset selection signal is generated at a logic high level H, the second bit OSEL<2>, the third bit OSEL<3>, the fourth bit OSEL<4>, the fifth bit OSEL<5>, and the six bit OSEL<6> are generated at a logic low level L.

An operation including generating, by the offset code signal generation circuit 242, the offset code signal OCD<1:4> based on an input value of the code signal CD<1:4> and the test offset signal TSP<1:2> is described with reference to FIG. 8. In this example, an output values of the offset code signal OCD<1:4> are shown in the table as decimal values as follows.

The offset code signal generation circuit 242 generates the offset code signal OCD<1:4> having an output value “7” when an input value of the code signal CD<1:4> is a decimal value “8” and logic level combinations of the test offset signal TSP<1:2> are “00”, “01”, “10”, or “11”. The offset code signal generation circuit 242 generates the offset code signal OCD<1:4> having an output value “7” when an input value of the code signal CD<1:4> is a decimal value “7” and logic level combinations of the test offset signal TSP<1:2> are “00”, “01”, “10”, or “11”.

The offset code signal generation circuit 242 generates the offset code signal OCD<1:4> having an output value “5” when an input value of the code signal CD<1:4> is a decimal value “6” and logic level combinations of the test offset signal TSP<1:2> are “00”, “01”, or “10”. The offset code signal generation circuit 242 generates the offset code signal OCD<1:4> having an output value “6” when an input value of the code signal CD<1:4> is a decimal value “6” and a logic level combination of the test offset signal TSP<1:2> is “11”.

The offset code signal generation circuit 242 generates the offset code signal OCD<1:4> having an output value “5” when an input value of the code signal CD<1:4> is a decimal value “5” and logic level combinations of the test offset signal TSP<1:2> are “00”, “01”, “10”, or “11”.

The offset code signal generation circuit 242 may generate the offset code signal OCD<1:4> having an output value “3” when an input value of the code signal CD<1:4> is a decimal value “4” and logic level combinations of the test offset signal TSP<1:2> are “00” or “01”. The offset code signal generation circuit 242 generates the offset code signal OCD<1:4> having an output value “4” when an input value of the code signal CD<1:4> is a decimal value “4” and logic level combinations of the test offset signal TSP<1:2> are “10” or “11”.

The offset code signal generation circuit 242 generates the offset code signal OCD<1:4> having an output value “3” when an input value of the code signal CD<1:4> is a decimal value “3” and logic level combinations of the test offset signal TSP<1:2> are “00”, “01”, “10”, or “11”.

The offset code signal generation circuit 242 generates the offset code signal OCD<1:4> having an output value “1” when an input value of the code signal CD<1:4> is a decimal value “2” and a logic level combination of the test offset signal TSP<1:2> is “00”. The offset code signal generation circuit 242 generates the offset code signal OCD<1:4> having an output value “2” when an input value of the code signal CD<1:4> is a decimal value “2” and logic level combinations of the test offset signal TSP<1:2> are “01”, “10”, or “11”.

The offset code signal generation circuit 242 generates the offset code signal OCD<1:4> having an output value “1” when an input value of the code signal CD<1:4> is a decimal value “1” and logic level combinations of the test offset signal TSP<1:2> are “00”, “01”, “10”, or “11”.

The offset code signal generation circuit 242 generates the offset code signal OCD<1:4> having an output value “0” when an input value of the code signal CD<1:4> is a decimal value “0” and logic level combinations of the test offset signal TSP<1:2> are “00”, “01”, “10”, or “11”.

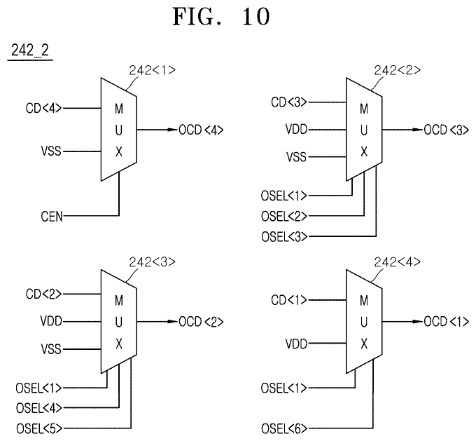

FIG. 10 is a block diagram illustrating an embodiment of the offset selection circuit 242_2 for example, as included in the offset code signal generation circuit 242. The offset selection circuit 242_2 includes a first multiplexer (MUX) 242<1>, a second multiplexer (MUX) 242<2>, a third multiplexer (MUX) 242<3>, and a fourth multiplexer (MUX) 242<4>.

The first multiplexer 242<1> outputs a fourth bit CD<4> of the code signal as a fourth bit OCD<4> of the offset code signal when the operation enable signal CEN is disabled at a logic low level. The first multiplexer 242<1> outputs a ground voltage VSS as the fourth bit OCD<4> of the offset code signal when the operation enable signal CEN is enabled at a logic high level. The ground voltage VSS may be a common ground voltage and may include a voltage at a logic low level.

The second multiplexer 242<2> outputs a third bit CD<3> of the code signal as a third bit OCD<3> of the offset code signal when the first bit OSEL<1> of the offset selection signal is enabled at a logic high level. The second multiplexer 242<2> outputs a power supply voltage VDD as the third bit OCD<3> of the offset code signal when the second bit OSEL<2> of the offset selection signal is enabled at a logic high level. The second multiplexer 242<2> outputs the ground voltage VSS as the third bit OCD<3> of the offset code signal when the third bit OSEL<3> of the offset selection signal is enabled at a logic high level. The power supply voltage VDD may be a common power supply voltage and may include a voltage at a logic high level.

The third multiplexer 242<3> outputs a second bit CD<2> of the code signal as a second bit OCD<2> of the offset code signal when the first bit OSEL<1> of the offset selection signal is enabled at a logic high level. The third multiplexer 242<3> outputs the power supply voltage VDD as the second bit OCD<2> of the offset code signal when the fourth bit OSEL<4> of the offset selection signal is enabled at a logic high level. The third multiplexer 242<3> outputs the ground voltage VSS as the second bit OCD<2> of the offset code signal when the fifth bit OSEL<5> of the offset selection signal is enabled at a logic high level.

The fourth multiplexer 242<4> outputs a first bit CD<1> of the code signal as a first bit OCD<1> of the offset code signal when the first bit OSEL<1> of the offset selection signal is enabled at a logic high level. The fourth multiplexer 242<4> outputs the power supply voltage VDD as the first bit OCD<1> of the offset code signal when the sixth bit OSEL<6> of the offset selection signal is enabled at a logic high level.

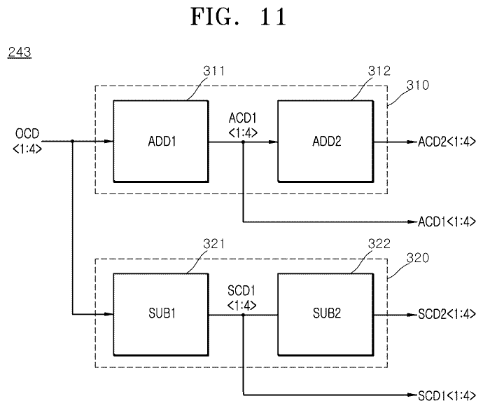

FIG. 11 is a block diagram illustrating an embodiment of the arithmetic circuit 243, for example, as included in the training circuit 240 of FIG. 2. The arithmetic circuit 243 includes an addition circuit 310 and a subtraction circuit 320.

The addition circuit 310 includes a first adder ADD1 311 and a second adder ADD2 312. The first adder 311 generates the first addition code signal ACD1<1:4> by performing a first addition operation on the offset code signal OCD<1:4>. The first adder 311 generates the first addition code signal ACD1<1:4> by up-counting the offset code signal OCD<1:4> once. Up-counting once includes adding a value of “1” to the previous value. The first addition operation may be an operation including up-counting the offset code signal OCD<1:4>once or adding a value of 1. The second adder 312 generates the second addition code signal ACD2<1:4> by performing a second addition operation on the first addition code signal ACD1<1:4>. The second adder 312 generates the second addition code signal ACD2<1:4> by up-counting the first addition code signal ACD1<1:4> once. The second addition operation may be an operation including up-counting the offset code signal OCD<1:4> twice or adding a value of “2” to the offset code signal OCD<1:4>. The addition circuit 310 generates the first addition code signal ACD1<1:4> by performing a first addition operation on the offset code signal OCD<1:4>. The addition circuit 310 generates the second addition code signal ACD2<1:4> by performing a second addition operation on the offset code signal OCD<1:4>.

The subtraction circuit 320 includes a first subtractor SUB1 321 and a second subtractor SUB2 322. The first subtractor 321 generates the first subtraction code signal SCD1<1:4> by performing a first subtraction operation on the offset code signal OCD<1:4>. The first subtractor 321 generates the first subtraction code signal SCD1<1:4> by down-counting the offset code signal OCD<1:4> once. Down-counting once includes subtracting a value of “1” from the previous value. The first subtraction operation may be an operation including down-counting the offset code signal OCD<1:4> once or subtracting a value of 1. The second subtractor 322 generates the second subtraction code signal SCD2<1:4> by performing a second subtraction operation on the first subtraction code signal SCD1<1:4>. The second subtractor 322 generates the second subtraction code signal SCD2<1:4> by down-counting the first subtraction code signal SCD1<1:4> once. The second subtraction operation may be an operation including down-counting the offset code signal OCD<1:4> twice or subtracting a value of “2” from the offset code signal OCD<1:4>. The subtraction circuit 320 generates the first subtraction code signal SCD1<1:4> by performing a first subtraction operation on the offset code signal OCD<1:4>. The subtraction circuit 320 generates the second subtraction code signal SCD2<1:4> by performing a second subtraction operation on the offset code signal OCD<1:4>.

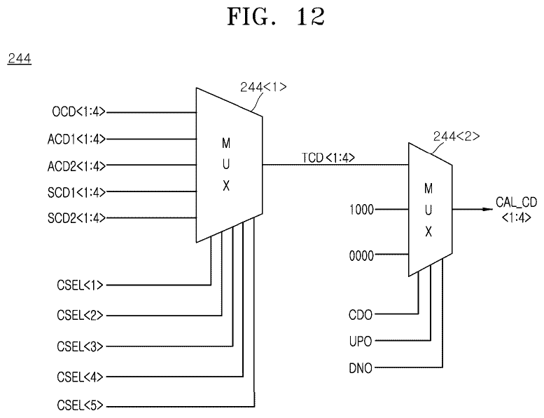

FIG. 12 is a block diagram illustrating an embodiment of the code selection circuit 244, for example, as included in the training circuit 240. The code selection circuit 244 includes a fifth multiplexer (MUX) 244<1> and a sixth multiplexer (MUX) 244<2>.

The fifth multiplexer 244<1> outputs the offset code signal OCD<1:4> as a transfer code signal TCD<1:4> when the first bit CSEL<1> of the operation selection signal is enabled at a logic high level. The fifth multiplexer 244<1> outputs the first addition code signal ACD1<1:4> as the transfer code signal TCD<1:4> when the second bit CSEL<2> of the operation selection signal is enabled at a logic high level. The fifth multiplexer 244<1> outputs the second addition code signal ACD2<1:4> as the transfer code signal TCD<1:4>when the third bit CSEL<3> of the operation selection signal is enabled at a logic high level. The fifth multiplexer 244<1> outputs the first subtraction code signal SCD1<1:4> as the transfer code signal TCD<1:4> when the fourth bit CSEL<4> of the operation selection signal is enabled at a logic high level. The fifth multiplexer 244<1> outputs the second subtraction code signal SCD2<1:4> as the transfer code signal TCD<1:4> when the fifth bit CSEL<5> of the operation selection signal is enabled at a logic high level. The fifth multiplexer 244<1> is illustrated as one circuit, but may be implemented with four similar circuits, one for each of the four bits of the offset code signal OCD<1:4>.

The sixth multiplexer 244<2> outputs the transfer code signal TCD<1:4> as the op-code signal CAL_CD<1:4> when the code output signal CDO is enabled at a logic high level. The sixth multiplexer 244<2> outputs a binary value “1000” as the op-code signal CAL_CD<1:4> when the upper limit output signal UPO is enabled at a logic high level. The binary value “1000” indicates a decimal value “8”. The sixth multiplexer 244<2> outputs a binary value “0000” as the op-code signal CAL_CD<1:4> when the lower limit output signal DNO is enabled at a logic high level. The binary value “0000” indicates a decimal value “0”. The sixth multiplexer 244<2> is illustrated as one circuit, but may be implemented with four similar circuits, one for each of the four bits of the transfer code signal TCD<1:4>.

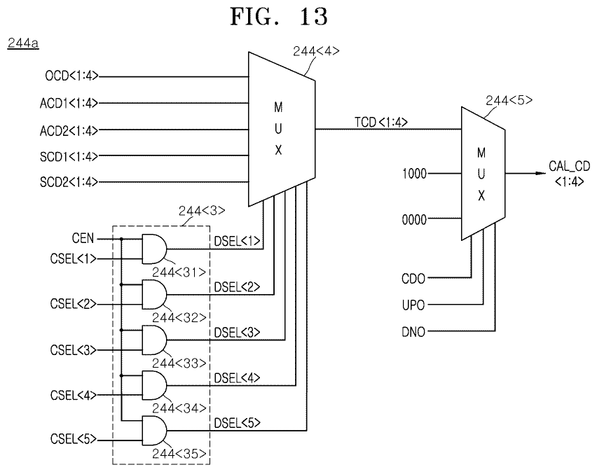

FIG. 13 is a block diagram illustrating another embodiment of the code selection circuit 244, for example, as included in the training circuit 240. The code selection circuit 244a includes a delay selection signal generation circuit 244<3>, a seventh multiplexer (MUX) 244<4>, and an eighth multiplexer (MUX) 244<5>.

The delay selection signal generation circuit 244<3> implemented with AND gates 244<31>, 244<32>, 244<33>, 244<34>, and 244<35>. The delay selection signal generation circuit 244<3> generates a delay selection signal DSEL<1:5> by buffering the operation selection signal CSEL<1:5> when the operation enable signal CEN is enabled at a logic high level. The delay selection signal generation circuit 244<3> generates the delay selection signal DSEL<1:5>, where all of the first through fifth bits are disabled at a logic low level when the operation enable signal CEN is disabled at a logic low level.

The seventh multiplexer 244<4> outputs the offset code signal OCD<1:4> as the transfer code signal TCD<1:4> when the first bit DSEL<1> of the delay selection signal is enabled at a logic high level. The seventh multiplexer 244<4> outputs the first addition code signal ACD1<1:4> as the transfer code signal TCD<1:4> when the second bit DSEL<2> of the delay selection signal is enabled at a logic high level. The seventh multiplexer 244<4> outputs the second addition code signal ACD2<1:4> as the transfer code signal TCD<1:4> when the third bit DSEL<3> of the delay selection signal is enabled at a logic high level. The seventh multiplexer 244<4> outputs the first subtraction code signal SCD1<1:4> as the transfer code signal TCD<1:4> when the fourth bit DSEL<4> of the delay selection signal is enabled at a logic high level. The seventh multiplexer 244<4> outputs the second subtraction code signal SCD2<1:4> as the transfer code signal TCD<1:4> when the fifth bit DSEL<5> of the delay selection signal is enabled at a logic high level. The seventh multiplexer 244<4> is illustrated as one circuit, but may be implemented with four similar circuits, one for each of the four bits of the offset code signal OCD<1:4>.

The eighth multiplexer 244<5> outputs the transfer code signal TCD<1:4> as the op-code signal CAL_CD<1:4> when the code output signal CDO is enabled at a logic high level. The eighth multiplexer 244<5> outputs a binary value “1000” as the op-code signal CAL_CD<1:4> when the upper limit output signal UPO is enabled at a logic high level. The binary value “1000” indicates a decimal value “8”. The eighth multiplexer 244<5> outputs the binary value “0000” as the op-code signal CAL_CD<1:4> when the lower limit output signal DNO is enabled at a logic high level. The binary value “0000” indicates a decimal value “0”. The eighth multiplexer 244<5> is illustrated as one circuit, but may be implemented with four similar circuits, one for each of the four bits of the transfer code signal TCD<1:4>.

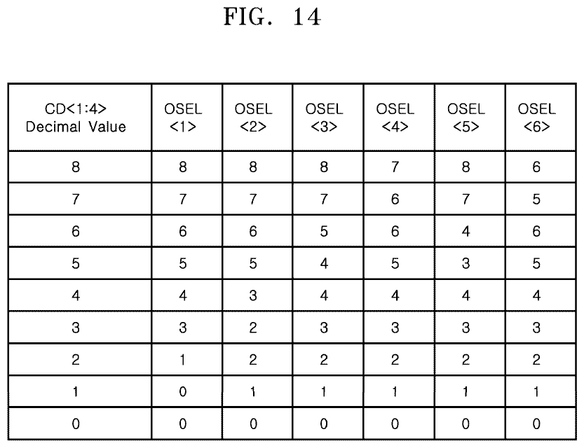

Values related to a post-training operation of the semiconductor chip 1 according to an embodiment of the present disclosure are shown in the table of FIG. 14. In this example, an operation including adjusting decimal values of the code signal CD<1:4> is described as follows.

When the decimal value of the code signal CD<1:4> is input as “1” and the first bit OSEL<1> of the offset selection signal is enabled at a logic high level, the training circuit 240 generates the op-code signal CAL_CD<1:4> by changing the decimal value of the code signal CD<1:4> from “1” to “0” by performing a first subtraction operation on the code signal CD<1:4>. When the decimal value of the code signal CD<1:4> is input as “2” and the first bit OSEL<1> of the offset selection signal is enabled at a logic high level, the training circuit 240 generates the op-code signal CAL_CD<1:4> by changing the decimal value of the code signal CD<1:4> from “2” to “1” by performing a first subtraction operation on the code signal CD<1:4>.

When the decimal value of the code signal CD<1:4> is input as “3” and the second bit OSEL<2> of the offset selection signal is enabled at a logic high level, the training circuit 240 generates the op-code signal CAL_CD<1:4> by changing the decimal value of the code signal CD<1:4> from “3” to “2” by performing a first subtraction operation on the code signal CD<1:4>. When the decimal value of the code signal CD<1:4> is input as “4” and the second bit OSEL<2> of the offset selection signal is enabled at a logic high level, the training circuit 240 generates the op-code signal CAL_CD<1:4> by changing the decimal value of the code signal CD<1:4> from “4” to “3” by performing a first subtraction operation on the code signal CD<1:4>.

When the decimal value of the code signal CD<1:4> is input as “5” and the third bit OSEL<3> of the offset selection signal is enabled at a logic high level, the training circuit 240 generates the op-code signal CAL_CD<1:4> by changing the decimal value of the code signal CD<1:4> from “5” to “4” by performing a first subtraction operation on the code signal CD<1:4>. When the decimal value of the code signal CD<1:4> is input as “6” and the third bit OSEL<3> of the offset selection signal is enabled at a logic high level, the training circuit 240 generates the op-code signal CAL_CD<1:4> by changing the decimal value of the code signal CD<1:4> from “6” to “5” by performing a first subtraction operation on the code signal CD<1:4>.

When the decimal value of the code signal CD<1:4> is input as “7” and the fourth bit OSEL<4> of the offset selection signal is enabled at a logic high level, the training circuit 240 generates the op-code signal CAL_CD<1:4> by changing the decimal value of the code signal CD<1:4> from “7” to “6” by performing a first subtraction operation on the code signal CD<1:4>. When the decimal value of the code signal CD<1:4> is input as “8” and the fourth bit OSEL<4> of the offset selection signal is enabled at a logic high level, the training circuit 240 generates the op-code signal CAL_CD<1:4> by changing the decimal value of the code signal CD<1:4> from “8” to “7” by performing a first subtraction operation on the code signal CD<1:4>.

When the decimal value of the code signal CD<1:4> is input as “5” and the fifth bit OSEL<5> of the offset selection signal is enabled at a logic high level, the training circuit 240 generates the op-code signal CAL_CD<1:4> by changing the decimal value of the code signal CD<1:4> from “5” to “3” by performing a second subtraction operation (two instances of down-counting) on the code signal CD<1:4>. When the decimal value of the code signal CD<1:4> is input as “6” and the fifth bit OSEL<5> of the offset selection signal is enabled at a logic high level, the training circuit 240 may generate the op-code signal CAL_CD<1:4> by changing the decimal value of the code signal CD<1:4> from “6” to “4” by performing a second subtraction operation (two instances of down-counting) on the code signal CD<1:4>.

When the decimal value of the code signal CD<1:4> is input as “7” and the sixth bit OSEL<6> of the offset selection signal is enabled at a logic high level, the training circuit 240 generates the op-code signal CAL_CD<1:4> by changing the decimal value of the code signal CD<1:4> from “7” to “5” by performing a second subtraction operation (two instances of down-counting) on the code signal CD<1:4>. When the decimal value of the code signal CD<1:4> is “8” and the sixth bit OSEL<6> of the offset selection signal is enabled at a logic high level, the training circuit 240 generates the op-code signal CAL_CD<1:4> by changing the decimal value of the code signal CD<1:4> from “8” to “6” by performing a second subtraction operation (two instances of down-counting) on the code signal CD<1:4>.

As described above, the semiconductor chip 1, according to an embodiment of the present disclosure, can adjust the delay amount for the strobe signal DQS by changing the logic level combination of the code signal CD<1:4> that adjusts the delay amount for the strobe signal DQS in a memory chip that is selected by the chip ID CID<1:2> after the start of a post-training operation. The semiconductor chip 1 may variously adjust the delay amount for the strobe signal DQS by performing various arithmetic operations on the logic level combination of the code signal CD<1:4> that adjusts the delay amount for the strobe signal DQS in a memory chip that is selected by the chip ID CID<1:2> after the start of a post-training operation. The semiconductor chip 1 may generate the code signal CD<1:4> that adjusts the delay amount for the strobe signal DQS in a pre-training operation, and may flexibly adjust the delay amount for the strobe signal DQS by additionally changing the logic level combination of the code signal CD<1:4> after the start of a post-training operation.

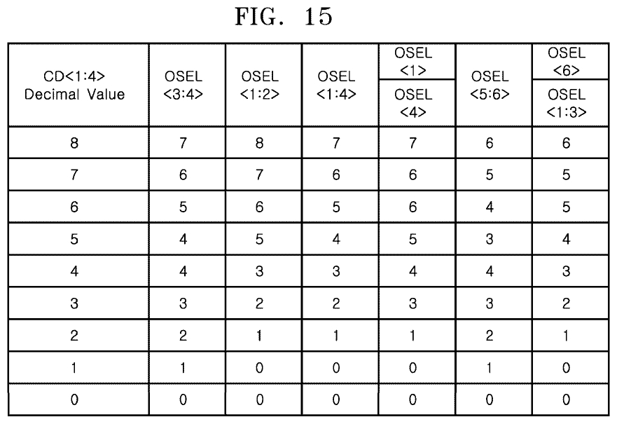

Values related to a post-training operation of the semiconductor chip 1 according to an embodiment of the present disclosure are shown in the table of FIG. 15. In this example, an operation including adjusting groups of four or eight decimal values of the code signal CD<1:4> is described as follows.

When the decimal values of the code signal CD<1:4> are “8”, “7”, “6”, or “5” and the third and fourth bits OSEL<3:4> of the offset selection signal are enabled at a logic high level, the training circuit 240 generates the op-code signal CAL_CD<1:4> by changing the decimal values of the code signal CD<1:4> from “8”, “7”, “6”, and “5” to “7”, “6”, “5”, and “4”, respectively, by performing a first subtraction operation on the code signal CD<1:4>.

When the decimal values of the code signal CD<1:4> are “4”, “3”, “2”, or “1” and the first and second bits OSEL<1:2> of the offset selection signal are enabled at a logic high level, the training circuit 240 generates the op-code signal CAL_CD<1:4> by changing the decimal values of the code signal CD<1:4> from “4”, “3”, “2”, and “1” to “3”, “2”, “1”, and “0”, respectively, by performing a first subtraction operation on the code signal CD<1:4>.

When the decimal values of the code signal CD<1:4> are “8”, “7”, “6”, “5”, “4”, “3”, “2”, or “1” and the first through fourth bits OSEL<1:4> of the offset selection signal are enabled at a logic high level, the training circuit 240 generates the op-code signal CAL_CD<1:4> by changing the decimal values of the code signal CD<1:4> from “8”, “7”, “6”, “5”, “4”, “3”, “2”, and “1” to “7”, “6”, “5”, “4”, “3”, “2”, “1”, and “0”, respectively, by performing a first subtraction operation on the code signal CD<1:4>.

When the decimal values of the code signal CD<1:4> are “8”, “7”, “2”, or “1” and the first bit OSEL<1> of the offset selection signal and the fourth bit OSEL<4> of the offset selection signal are enabled at a logic high level, the training circuit 240 generates the op-code signal CAL_CD<1:4> by changing the decimal values of the code signal CD<1:4> from “8” and “7” to “7” and “6”, respectively, and changing the decimal values of the code signal CD<1:4> from “2” and “1” to “1” and “0”, respectively, by performing a first subtraction operation on the code signal CD<1:4>.

When the decimal values of the code signal CD<1:4> are “8”, “7”, “6”, or “5” and the fifth and sixth bits OSEL<5:6> of the offset selection signal are enabled at a logic high level, the training circuit 240 generates the op-code signal CAL_CD<1:4> by changing the decimal values of the code signal CD<1:4> from “8”, “7”, “6”, and “5” to “6”, “5”, “4”, and “3”, respectively, by performing a second subtraction operation (two instances of down-counting) on the code signal CD<1:4>.

When the decimal values of the code signal CD<1:4> are “8”, “7”, “6”, “5”, “4”, “3”, “2”, and “1” and the first through third bits OSEL<1:3> of the offset selection signal and the sixth bit OSEL<6> of the offset selection signal are enabled at a logic high level, the training circuit 240 generates the op-code signal CAL_CD<1:4> by changing the decimal values of the code signal CD<1:4> from “8” and “7” to “6” and “5”, respectively, by performing a second subtraction operation (two instances of down-counting) on the code signal CD<1:4> and changing the decimal values of the code signal CD<1:4> from “6”, “5”, “4”, “3”, “2”, and “1” to “5”, “4”, “3”, “2”, “1”, and “0”, respectively, by performing a first subtraction operation on the code signal CD<1:4>.

As described above, the semiconductor chip 1 according to an embodiment of the present disclosure can adjust the delay amount for the strobe signal DQS by changing the logic level combination of the code signal CD<1:4> that adjusts the delay amount for the strobe signal DQS in a memory chip that is selected by the chip ID CID<1:2> after the start of a post-training operation. The semiconductor chip 1 may variously adjust the delay amount for the strobe signal DQS by performing various arithmetic operations on the logic level combination of the code signal CD<1:4> that adjusts the delay amount for the strobe signal DQS in a memory chip that is selected by the chip ID CID<1:2> after the start of a post-training operation. The semiconductor chip 1 may generate the code signal CD<1:4> that adjusts the delay amount for the strobe signal DQS in a pre-training operation, and may flexibly adjust the delay amount for the strobe signal DQS by additionally changing the logic level combination of the code signal CD<1:4> after the start of a post-training operation.

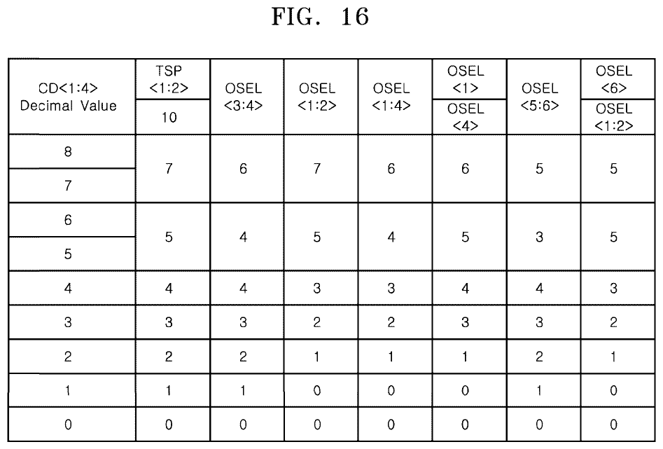

Values related to a post-training operation of the semiconductor chip 1 according to an embodiment of the present disclosure are shown in the table of FIG. 16. In this example, an operation including adjusting multiple decimal values of the code signal CD<1:4> after setting an offset of the code signal CD<1:4> when a logic level combination of the test offset signal TSP<1:2> is “10” is described as follows.

In a preliminary process, when a logic level combination of the test offset signal TSP<1:2> is “10”, the training circuit 240 adjusts some of the decimal values of the code signal CD<1:4> from “8” to “7” and from “6” to “5”, and maintains the decimal values of the code signal CD<1:4> for “4”, “3”, “2”, and “1”. These adjusted decimal values for the code signal CD<1:4> are included in the column under “TSP<1:2>” and the op-code signal CAL_CD<1:4> is generated from these adjusted decimal values for the code signal CD<1:4>.

After the preliminary process, when the third and fourth bits OSEL<3:4> of the offset selection signal are enabled at a logic high level, the training circuit 240 generates the op-code signal CAL_CD<1:4> by changing the adjusted decimal values of the code signal CD<1:4> from “7” and “5” to “6” and “4”, respectively, by performing a first subtraction operation on the adjusted values of the code signal CD<1:4>.

After the preliminary process, when the first and second bits OSEL<1:2> of the offset selection signal are enabled at a logic high level, the training circuit 240 generates the op-code signal CAL_CD<1:4> by changing the decimal values of the code signal CD<1:4> from “4”, “3”, “2”, and “1” to “3”, “2”, “1”, and “0”, respectively, by performing a first subtraction operation on the code signal CD<1:4>.

After the preliminary process, when the first through fourth bits OSEL<1:4> of the offset selection signal are enabled at a logic high level, the training circuit 240 generates the op-code signal CAL_CD<1:4> by changing the adjusted decimal values of the code signal CD<1:4> from “7” and “5” to “6” and “4”, respectively, by performing a first subtraction operation on the adjusted values of the code signal CD<1:4>. After the preliminary process, when the first through fourth bits OSEL<1:4> of the offset selection signal are enabled at a logic high level, the training circuit 240 generates the op-code signal CAL_CD<1:4> by changing the decimal values of the code signal CD<1:4> from “4”, “3”, “2”, and “1” to “3”, “2”, “1”, and “0”, respectively, by performing a first subtraction operation on the code signal CD<1:4>.

After the preliminary process, when the first bit OSEL<1> of the offset selection signal and the fourth bit OSEL<4> of the offset selection signal are enabled at a logic high level, the training circuit 240 generates the op-code signal CAL_CD<1:4> by changing the adjusted decimal value of the code signal CD<1:4> from “7” to “6” by performing a first subtraction operation on the adjusted values of the code signal CD<1:4>. After the preliminary process, when the first bit OSEL<1> of the offset selection signal and the fourth bit OSEL<4> of the offset selection signal are enabled at a logic high level, the training circuit 240 generates the op-code signal CAL_CD<1:4> by changing the decimal values of the code signal CD<1:4> from “2” and “1” to “1” and “0”, respectively, by performing a first subtraction operation on the code signal CD<1:4>.

After the preliminary process, when the fifth and sixth bits OSEL<5:6> of the offset selection signal are enabled at a logic high level, the training circuit 240 generates the op-code signal CAL_CD<1:4> by changing the adjusted decimal values of the code signal CD<1:4> from “7” and “5” to “5” and “3”, respectively, by performing a second subtraction operation (2 instances of down-counting) on the adjusted values of the code signal CD<1:4>.

After the preliminary process, when the first and second bits OSEL<1:2> of the offset selection signal and the sixth bit OSEL<6> of the offset selection signal are enabled at a logic high level, the training circuit 240 generates the op-code signal CAL_CD<1:4> by changing the decimal value of the adjusted code signal CD<1:4> from “7” to “5” by performing a second subtraction operation (2 instances of down-counting) on the adjusted values of the code signal CD<1:4>.

After the preliminary process, when the first and second bits OSEL<1:2> of the offset selection signal and the sixth bit OSEL<6> of the offset selection signal are enabled at a logic high level, the training circuit 240 generates the op-code signal CAL_CD<1:4> by changing the decimal values of the code signal CD<1:4> from “4”, “3”, “2”, and “1” to “3”, “2”, “1”, and “0”, respectively, by performing a first subtraction operation on the code signal CD<1:4>.

As described above, the semiconductor chip 1, according to an embodiment of the present disclosure, may adjust the delay amount for the strobe signal DQS by changing the logic level combination of the code signal CD<1:4> that adjusts the delay amount for the strobe signal DQS in a memory chip that is selected by the chip ID CID<1:2> after the start of a post-training operation. The semiconductor chip 1 may variously adjust the delay amount for the strobe signal DQS by performing various arithmetic operations on the logic level combinations of the code signal CD<1:4> that adjusts the delay amount for the strobe signal DQS in a memory chip that is selected by the chip ID CID<1:2> after the start of a post-training operation. The semiconductor chip 1 may generate the code signal CD<1:4> that adjusts the delay amount for the strobe signal DQS in a pre-training operation and may flexibly adjust the delay amount for the strobe signal DQS by additionally changing or adjusting the logic level combination of the code signal CD<1:4> after the start of a post-training operation.

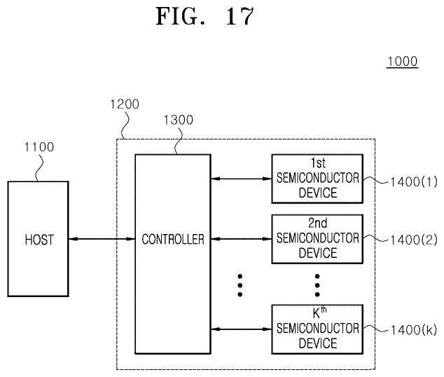

FIG. 17 is a block diagram illustrating an embodiment of an electronic system 1000 according to an embodiment of the present disclosure. As illustrated in FIG. 17, the electronic system 1000 includes a host 1100 and a semiconductor system 1200.

The host 1100 and the semiconductor system 1200 transmit signals to each other using an interface protocol. The interface protocol that is used between the host 1100 and the semiconductor system 1200 may include a multi-media card (MMC), an enhanced small disk interface (ESDI), integrated drive electronics (IDE), peripheral component interconnect-express (PCI-E), advanced technology attachment (ATA), serial ATA (SATA), parallel ATA (PATA), a serial attached SCSI (SAS), and a universal serial bus (USB).

The semiconductor system 1200 includes a controller 1300 and semiconductor devices 1400(K:1), where K is an integer value. The controller 1300 controls the semiconductor devices 1400(K:1) such that the semiconductor devices 1400(K:1) each perform a pre-training operation, a post-training operation, a read operation, and a write operation. The semiconductor devices 1400(K:1) each adjust the delay amount for the strobe signal DQS by changing the logic level combination of the code signal CD<1:4> that adjusts the delay amount for the strobe signal DQS when the semiconductor device is selected by the chip ID CID<1:2> after the start of a post-training operation. The semiconductor devices 1400(K:1) may each variously adjust the delay amount for the strobe signal DQS by performing various arithmetic operations on the logic level combination of the code signal CD<1:4> that adjusts the delay amount for the strobe signal DQS when the semiconductor device is selected by the chip ID CID<1:2> after the start of a post-training operation. Each of the semiconductor devices 1400(K:1) generates the code signal CD<1:4> that adjusts the delay amount for the strobe signal DQS in a pre-training operation, and flexibly adjusts the delay amount for the strobe signal DQS by additionally changing the logic level combination of the code signal CD<1:4> after the start of a post-training operation.

The controller 1300 may be implemented with the same circuitry as the base chip 10 illustrated in FIG. 1. The semiconductor devices 1400(K:1) may each be implemented with the same circuitry as any of the first memory chip 20, the second memory chip 30, the third memory chip 40, and the fourth memory chip 50 illustrated in FIG. 1. Each of the semiconductor devices 1400(K:1) may be implemented with one of dynamic random access memory (DRAM), phase change random access memory (PRAM), resistive random access memory (RRAM), magnetic random access memory (MRAM), and ferroelectric random access memory (FRAM).

Concepts are disclosed in conjunction with various embodiments as described above. Those skilled in the art will understand that various modifications, additions, and substitutions are possible, without departing from the scope and spirit of the present disclosure. Accordingly, the embodiments disclosed in the present specification should be considered not from a restrictive standpoint but rather from an illustrative standpoint. Therefore, the scope of the present disclosure should not be limited to the foregoing embodiments. All changes within the meaning and range of equivalency of the claims are to be included within their scope.

What is claimed is:

1. A memory chip comprising:
a delay amount adjustment circuit configured to change a logic level combination of a code signal that adjusts a first delay amount for a strobe signal that is input or output through a conductive via based on a chip ID and a test mode signal after a start of a post-training operation and configured to generate an op-code signal by performing an arithmetic operation on the code signal; and
a data processing circuit configured to delay the strobe signal by a second delay amount that is based on the op-code signal, configured to latch internal data in synchronization with the strobe signal that is delayed by the second delay amount, and configured to output, as data, the internal data that are latched.

2. The memory chip of claim 1, wherein:
the first delay amount is a delay amount of a replica delay circuit, and
the second delay amount is a delay amount of the conductive via.

3. The memory chip of claim 1, wherein the code signal is a signal that is generated to adjust the delay amount for the strobe signal through a replica delay circuit having a delay amount for the conductive via after a start of a pre-training operation that is performed before the post-training operation is performed.

4. The memory chip of claim 1, wherein the delay amount adjustment circuit comprises:
a replica delay circuit configured to generate a transfer strobe signal by delaying the strobe signal by the first delay amount that is adjusted based on the code signal;
a code signal generation circuit configured to adjust a logic level combination of the code signal by comparing phases of the strobe signal and the transfer strobe signal;
a training control circuit configured to generate an operation enable signal that is enabled when the chip ID is at a preset logic level combination; and
a training circuit configured to change the logic level combination of the code signal based on the test mode signal when the operation enable signal is enabled and configured to generate the op-code signal by performing an arithmetic operation on the code signal.

5. The memory chip of claim 4, wherein the training circuit comprises:
an operation control signal generation circuit configured to generate a test offset signal that changes the logic level combination of the code signal based on the test mode signal, configured to generate an operation selection signal that selects results of the arithmetic operation based on the test mode signal, configured to detect an input value of the code signal, and configured to generate a code output signal, an upper limit output signal, and a lower limit output signal that selects an upper limit value and a lower limit value based on the test mode signal;
an offset code signal generation circuit configured to detect the input value of the code signal and configured to generate an offset code signal by changing the logic level combination of the code signal based on the operation enable signal and the test offset signal;
an arithmetic circuit configured to generate a first addition code signal and a second addition code signal by performing a first addition operation and a second addition operation on the offset code signal and configured to generate a first subtraction code signal and a second subtraction code signal by performing a first subtraction operation and a second subtraction operation on the offset code signal; and
a code selection circuit configured to output any of the offset code signal, the first addition code signal, the second addition code signal, the first subtraction code signal, and the second subtraction code signal as the op-code signal based on the operation selection signal, the code output signal, the upper limit output signal, and the lower limit output signal.

6. The memory chip of claim 5, wherein the offset code signal generation circuit comprises:
an offset control circuit configured to detect the input value of the code signal and configured to generate an offset selection signal based on the operation enable signal and the test offset signal; and
an offset selection circuit configured to generate the offset code signal by changing the logic level combination of the code signal based on the operation enable signal and the offset selection signal.

7. The memory chip of claim 5, wherein the arithmetic circuit comprises:
a first adder configured to generate the first addition code signal by performing the first addition operation on the offset code signal;
a second adder configured to generate the second addition code signal by performing the first addition operation on the first addition code signal;
a first subtractor configured to generate the first subtraction code signal by performing the first subtraction operation on the offset code signal; and
a second subtractor configured to generate the second subtraction code signal by performing the first subtraction operation on the first subtraction code signal.

8. The memory chip of claim 5, wherein the code selection circuit comprises:
a first multiplexer configured to output any of the offset code signal, the first addition code signal, the second addition code signal, the first subtraction code signal, and the second subtraction code signal as a transfer code signal based on the operation selection signal; and
a second multiplexer configured to output the transfer code signal as the op-code signal when the code output signal is enabled, configured to output the upper limit value as the op-code signal when the upper limit output signal is enabled, and configured to output the lower limit value as the op-code signal when the lower limit output signal is enabled.

9. A semiconductor chip comprising:
a first memory chip configured to generate a first op-code signal by performing an arithmetic operation on a first code signal that adjusts a delay amount for a strobe signal that is input through a first conductive via when a chip identification (ID) is at a first logic level combination after a start of a post-training operation and configured to output first data through a second conductive via by delaying the strobe signal by a delay amount that is adjusted based on the first op-code signal; and
a second memory chip configured to generate a second op-code signal by performing an arithmetic operation on a second code signal that adjusts the delay amount for the strobe signal that is input through the first conductive via when the chip ID is at a second logic level combination after the start of the post-training operation, and configured to output second data through a third conductive via by delaying the strobe signal by a delay amount that is adjusted based on the second op-code signal.

10. The semiconductor chip of claim 9, wherein the second memory chip is stacked over the first memory chip and the first through third conductive vias.

11. The semiconductor chip of claim 9, wherein the first memory chip comprises:
a first delay amount adjustment circuit configured to change a logic level combination of the first code signal based on a test mode signal when the chip ID is at the first logic level combination after the start of the post-training operation and configured to generate the first op-code signal by performing an arithmetic operation on the first code signal; and
a first data processing circuit configured to delay the strobe signal by a second delay amount that is based on the first op-code signal, configured to latch first internal data in synchronization with the strobe signal that is delayed, and configured to output, as the first data, the first internal data that are latched through the second conductive via.

12. The semiconductor chip of claim 11, wherein the first delay amount adjustment circuit comprises:
a first replica delay circuit configured to generate a first transfer strobe signal by delaying the strobe signal by a first delay amount that is adjusted based on the first code signal;
a first code signal generation circuit configured to adjust the logic level combination of the first code signal by comparing phases of the strobe signal and the first transfer strobe signal;
a first training control circuit configured to generate a first operation enable signal that is enabled when the chip ID is at the first logic level combination; and
a first training circuit configured to change the logic level combination of the first code signal based on the test mode signal when the first operation enable signal is enabled and configured to generate the first op-code signal by performing an arithmetic operation on the first code signal.

13. The semiconductor chip of claim 12, wherein the first training circuit comprises:
a first operation control signal generation circuit configured to generate a first test offset signal that changes the logic level combination of the first code signal based on the test mode signal, configured to generate a first operation selection signal that selects results of the arithmetic operation based on the test mode signal, configured to detect an input value of the first code signal, and configured to generate a first code output signal, a first upper limit output signal, and a first lower limit output signal that selects an upper limit value and a lower limit value based on the test mode signal;
a first offset code signal generation circuit configured to detect the input value of the first code signal and configured to generate a first offset code signal by changing the logic level combination of the first code signal based on the first operation enable signal and the first test offset signal;
a first arithmetic circuit configured to generate a first addition code signal and a second addition code signal by performing a first addition operation and a second addition operation on the first offset code signal and configured to generate a first subtraction code signal and a second subtraction code signal by performing a first subtraction operation and a second subtraction operation on the first offset code signal; and
a first code selection circuit configured to output any of the first offset code signal, the first addition code signal, the second addition code signal, the first subtraction code signal, and the second subtraction code signal as the first op-code signal based on the first operation selection signal, the first code output signal, the first upper limit output signal, and the first lower limit output signal when the first operation enable signal is enabled.

14. The semiconductor chip of claim 13, wherein the first offset code signal generation circuit comprises:
a first offset control circuit configured to detect the input value of the first code signal and configured to generate a first offset selection signal based on the first operation enable signal and the first test offset signal; and
a first offset selection circuit configured to generate the first offset code signal by changing the logic level combination of the first code signal based on the first operation enable signal and the first offset selection signal.

15. The semiconductor chip of claim 13, wherein the first arithmetic circuit comprises:
a first adder configured to generate the first addition code signal by performing the first addition operation on the first offset code signal;
a second adder configured to generate the second addition code signal by performing the first addition operation on the first addition code signal;
a first subtractor configured to generate the first subtraction code signal by performing the first subtraction operation on the first offset code signal; and
a second subtractor configured to generate the second subtraction code signal by performing the first subtraction operation on the first subtraction code signal.

16. The semiconductor chip of claim 13, wherein the first code selection circuit comprises:
a first delay selection signal generation circuit configured to generate a first delay selection signal by buffering the first operation selection signal when the first operation enable signal is enabled;
a first multiplexer configured to output one of the first offset code signal, the first addition code signal, the second addition code signal, the first subtraction code signal, and the second subtraction code signal as a first transfer code signal based on the first delay selection signal; and
a second multiplexer configured to output the first transfer code signal as the first op-code signal when the first code output signal is enabled, configured to output the upper limit value as the first op-code signal when the first upper limit output signal is enabled, and configured to output the lower limit value as the first op-code signal when the first lower limit output signal is enabled.

17. The semiconductor chip of claim 9, wherein the second memory chip comprises:
a second delay amount adjustment circuit configured to change a logic level combination of the second code signal based on a test mode signal when the chip ID is at the second logic level combination after the start of the post-training operation and configured to generate a second op-code signal by performing an arithmetic operation on the second code signal; and
a second data processing circuit configured to delay the strobe signal by a second delay amount that is based on the second op-code signal, configured to latch second internal data in synchronization with the strobe signal that is delayed, and configured to output, as the second data, the second internal data that are latched through the third conductive via.

18. The semiconductor chip of claim 17, wherein the second delay amount adjustment circuit comprises:
a second replica delay circuit configured to generate a second transfer strobe signal by delaying the strobe signal by a third delay amount that is adjusted based on the second code signal;
a second code signal generation circuit configured to adjust the logic level combination of the second code signal by comparing phases of the strobe signal and the second transfer strobe signal;
a second training control circuit configured to generate a second operation enable signal that is enabled when the chip ID has the second logic level combination; and
a second training circuit configured to change the logic level combination of the second code signal based on the test mode signal when the second operation enable signal is enabled and configured to generate the second op-code signal by performing an arithmetic operation on the second code signal.

19. The semiconductor chip of claim 18, wherein the second training circuit comprises:
a second operation control signal generation circuit configured to generate a second test offset signal that changes the logic level combination of the second code signal based on the test mode signal, configured to generate a second operation selection signal that selects results of the arithmetic operation based on the test mode signal, configured to detect an input value of the second code signal, and configured to generate a second code output signal, a second upper limit output signal, and a second lower limit output signal that selects an upper limit value and a lower limit value based on the test mode signal;
a second offset code signal generation circuit configured to detect the input value of the second code signal and configured to generate a second offset code signal by changing the logic level combination of the second code signal based on the second operation enable signal and the second test offset signal;
a second arithmetic circuit configured to generate a third addition code signal and a fourth addition code signal by performing a first addition operation and a second addition operation on the second offset code signal and configured to generate a third subtraction code signal and a fourth subtraction code signal by performing a first subtraction operation and a second subtraction operation on the second offset code signal; and
a second code selection circuit configured to output any of the second offset code signal, the third addition code signal, the fourth addition code signal, the third subtraction code signal, and the fourth subtraction code signal as the second op-code signal based on the second operation selection signal, the second code output signal, the second upper limit output signal, and the second lower limit output signal when the second operation enable signal is enabled.

20. The semiconductor chip of claim 19, wherein the second offset code signal generation circuit comprises:
a second offset control circuit configured to detect the input value of the second code signal and configured to generate a second offset selection signal based on the second operation enable signal and the second test offset signal; and
a second offset selection circuit configured to generate the second offset code signal by changing the logic level combination of the second code signal based on the second operation enable signal and the second offset selection signal.

21. The semiconductor chip of claim 19, wherein the second arithmetic circuit comprises:
a third adder configured to generate the third addition code signal by performing the first addition operation on the second offset code signal;
a fourth adder configured to generate the fourth addition code signal by performing the first addition operation on the third addition code signal;
a third subtractor configured to generate the third subtraction code signal by performing the first subtraction operation on the second offset code signal; and
a fourth subtractor configured to generate the fourth subtraction code signal by performing the first subtraction operation on the second subtraction code signal.

22. The semiconductor chip of claim 19, wherein the second code selection circuit comprises:
a second delay selection signal generation circuit configured to generate a second delay selection signal by buffering the second operation selection signal when the second operation enable signal is enabled;
a third multiplexer configured to output one of the second offset code signal, the third addition code signal, the fourth addition code signal, the third subtraction code signal, and the fourth subtraction code signal as a second transfer code signal based on the second delay selection signal; and
a fourth multiplexer configured to output the second transfer code signal as the second op-code signal when the second code output signal is enabled, configured to output the upper limit value as the second op-code signal when the second upper limit output signal is enabled, and configured to output the lower limit value as the second op-code signal when the second lower limit output signal is enabled.

23. A semiconductor chip comprising:
a first memory chip, associated with a first chip identification (ID), configured to, in response to receiving the first chip ID, generate a first op-code signal by performing an arithmetic operation on a first code signal that adjusts a delay amount for a strobe signal that is input through a first signal path and adjust the delay amount for the strobe signal based on the first op-code signal; and
a second memory chip, associated with a second chip identification (ID), configured to, in response to receiving the second chip ID, generate a second op-code signal by performing an arithmetic operation on a second code signal that adjusts the delay amount for the strobe signal that is input through a second signal path and adjust the delay amount for the strobe signal based on the second op-code signal.

24. The semiconductor chip of claim 23, wherein the first and second signal paths are implemented with a plurality of conductive vias or a plurality of segments of wire bonding.

25. The semiconductor chip of claim 23, wherein the first memory chip and the second memory chip are stacked over the first signal path and the second signal path.

26. The semiconductor chip of claim 23, wherein:
the first memory chip adjusts the delay amount for the strobe signal when the chip ID is at a first logic level combination, and
the second memory chip adjusts the delay amount for the strobe signal when the chip ID is at a second logic level combination.

27. The semiconductor chip of claim 23, wherein the first memory chip comprises:
a first delay amount adjustment circuit configured to change a logic level combination of the first code signal that adjusts the first delay amount of the strobe signal based on the chip ID and a test mode signal and configured to generate the first op-code signal by performing an arithmetic operation on the first code signal; and
a first data processing circuit configured to delay the strobe signal by a second delay amount that is based on the first op-code signal, configured to latch first internal data in synchronization with the strobe signal that is delayed by the second delay amount, and configured to output, as first data, the first internal data that are latched through the first signal path.

28. The semiconductor chip of claim 27, wherein:
the first delay amount is a delay amount for a first replica delay circuit, and
the second delay amount is a delay amount for the first signal path.

29. The semiconductor chip of claim 23, wherein the second memory chip comprises:
a second delay amount adjustment circuit configured to change a logic level combination of the second code signal that adjusts a third delay amount for the strobe signal based on the chip ID and a test mode signal and configured to generate the second op-code signal by performing an arithmetic operation on the second code signal; and
a second data processing circuit configured to delay the strobe signal by a fourth delay amount that is based on the second op-code signal, configured to latch second internal data in synchronization with the strobe signal that is delayed by the fourth delay amount, and configured to output, as second data, the second internal data that are latched through the second signal path.

30. The semiconductor chip of claim 29, wherein:
the third delay amount is a delay amount for a second replica delay circuit, and
the fourth delay amount is a delay amount for the second signal path.

31. A method comprising:
generating an op-code signal by performing an arithmetic operation on a code signal that adjusts a delay amount for a strobe signal;
adjusting the delay amount for the strobe signal based on the op-code signal;
delaying the strobe signal by the adjusted delay amount;
latching internal data in synchronization with the strobe signal that is delayed by the adjusted delay amount; and
outputting the latched internal data.

32. The method of claim 31, wherein the adjusted delay amount is based on a signal path for the strobe signal.
